(19) United States
(12) Patent Application Publication
(10) Pub. No.: US 2026/0353585 A1
(43) Pub. Date: Nov. 5, 2026

(54) MOTOR CONTROL DEVICE

(71) Applicant: SANYO DENKI CO., LTD., Tokyo (JP)

(72) Inventors: Takao Oshimori, Tokyo (JP); Mitsuru Takasugi, Tokyo (JP); Kazuki Fujita, Tokyo (JP); Yukiya Hashimoto, Tokyo (JP)

(21) Appl. No.: 19/557,870

(22) Filed: Mar. 5, 2026

(30) Foreign Application Priority Data
Mar. 7, 2025 (JP) 2025-036666

(51) Int. Cl. H05K 7/14

(52) U.S. Cl. CPC H05K 7/1432; H05K 7/1407; H05K 7/1417

(57) ABSTRACT

A motor control device includes a first board including a first mounting surface on which an electronic component is mounted, a second board extending parallel to the first board and including a second mounting surface larger than the first mounting surface, a die-cast frame configured to support the first board and the second board, and an attachment configured to attach the motor control device to a fixing member. The first board is provided at a position where the first board is sandwiched between the second board and the die-cast frame, in a direction orthogonal to the first mounting surface. At least a part of the second board is provided so as to cover the first board, when viewed from the direction orthogonal to the first mounting surface.

### CROSS-REFERENCE TO RELATED APPLICATIONS

This application is based on and claims priority under 35 USC 119 from Japanese Patent Application No. 2025-036666 filed on Mar. 7, 2025, the entire content of which is incorporated herein by reference.

### TECHNICAL FIELD

The present disclosure relates to a motor control device.

### BACKGROUND ART

JP2008-311468A discloses an electronic apparatus having a plurality of printed wiring boards.

In a case where a plurality of boards are provided in an electronic device, there is a problem that attachment of the boards becomes complicated in an assembly process depending on arrangement o screw holes.

In addition, among the electronic devices, in particular, a motor control device may be used by being fixed to another device, a wall surface, or the like. In this case, a screw hole for attaching the motor control device is separately required, which causes a problem that the entire motor control device is increased in size.

### SUMMARY OF INVENTION

Aspect of non-limiting embodiments of the present disclosure relates to provide a motor control device that reduces an increase in size and is easy to assemble.

Aspects of certain non-limiting embodiments of the present disclosure address the features discussed above and/or other features not described above. However, aspects of the non-limiting embodiments are not required to address the above features, and aspects of the non-limiting embodiments of the present disclosure may not address features described above.

According to an aspect of the present disclosure, there is provided a motor control device including:
a first board including a first mounting surface on which an electronic component is mounted;
a second board extending parallel to the first board and including a second mounting surface larger than the first mounting surface;
a die-cast frame configured to support the first board and the second board; and
an attachment configured to attach the motor control device to a fixing member,
in which the first board is provided at a position where the first board is sandwiched between the second board and the die-cast frame, in a direction orthogonal to the first mounting surface,
at least a part of the second board is provided so as to cover the first board, when viewed from the direction orthogonal to the first mounting surface,
the die-cast frame has:
   a first screw hole for attaching the first board;
   a second screw hole for attaching the second board; and
   a third screw hole for attaching the attachment, and
when viewed from the direction orthogonal to the first mounting surface:
   the first screw hole and the second screw hole are provided at positions where the first screw hole and the second screw hole do not overlap each other; and
   the second screw hole and the third screw hole are provided at positions where the second screw hole and the third screw hole overlap each other.

### BRIEF DESCRIPTION OF DRAWINGS

Exemplary embodiment(s) of the present invention will be described in detail based on the following figures, wherein:

FIG. 1 is a perspective view illustrating a motor control device according to the present disclosure;

FIG. 2 is a sectional view taken along a line II-II in FIG. 1; and

FIG. 3 is a top view illustrating the motor control device according to the present disclosure.

### DESCRIPTION OF EMBODIMENTS

### Details of Embodiment of Present Disclosure

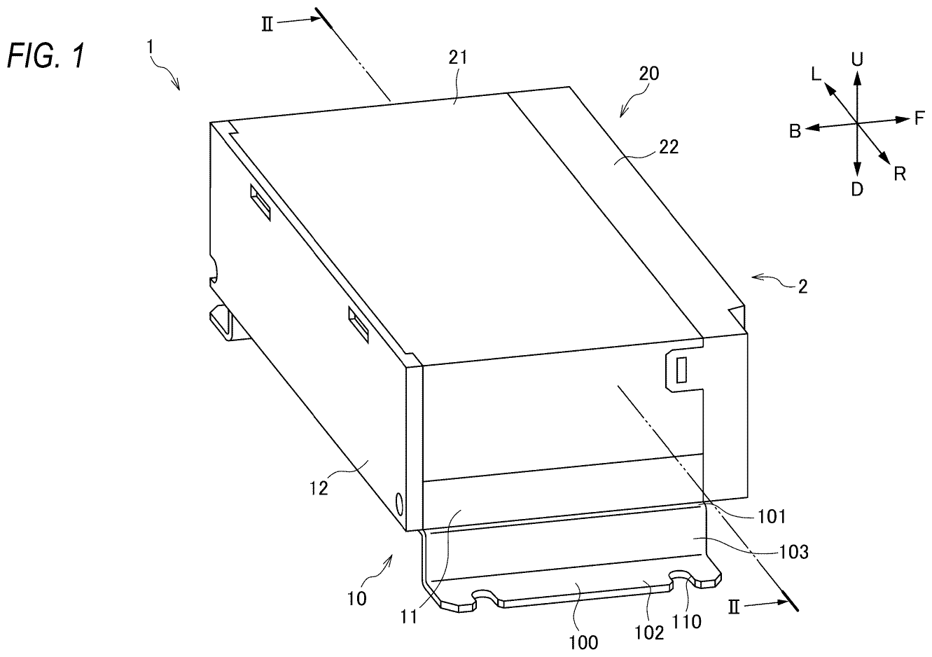

A specific example of a motor control device according to an embodiment of the present disclosure will be described below with reference to the drawings. Note that, the present disclosure is not limited to these examples, but is indicated by claims, and is intended to include all modifications within the meaning and scope equivalent to claims. Note that members having the same reference numerals as members already described in the description of the embodiment will not be described for convenience of description. The dimensions of each member illustrated in the drawings may be different from the actual dimensions of each member for convenience of description. Note that, U, D, R, L, F and B illustrated in FIG. 1 and the like indicate directions in a motor control device 1, where U is an upper direction, D is a lower direction, R is a right direction, L is a left direction, F is a front direction, and B is a rear direction.

The motor control device 1 according to the present embodiment will be described in detail with reference to FIGS. 1 to 3. FIG. 1 is a perspective view illustrating the motor control device 1 according to the embodiment of the present disclosure.

As illustrated in FIG. 1, the motor control device 1 includes a rectangular parallelepiped box-shaped frame 2 and an attachment 100.

The frame 2 is a member configured to support members provided therein. An accommodation space for accommodating the members is formed inside the frame 2. The frame 2 includes a die-cast frame 10 formed by metal die-casting and a resin frame 20 made of a resin. The frame 2 is formed by fitting the die-cast frame 10 and the resin frame 20 to each other.

The die-cast frame 10 includes a plate-shaped portion 11 configuring a lower surface (a surface in the lower direction D) of the frame 2, and a back surface portion 12 configuring a rear surface (a surface in the rear direction B) of the frame 2. The plate-shaped portion 11 is a plate-shaped portion extending in a front-rear direction and a left-right direction. The back surface portion 12 is a plate-shaped portion extending in an upper-lower direction and the left-right direction. A lower portion of the back surface portion 12 and a rear portion of the plate-shaped portion 11 are fixed to each other. The die-cast frame 10 is formed in a substantially L shape, when viewed from the left-right direction.

The resin frame 20 is a member configuring an upper surface, a front surface, and a part of left and right side surfaces of the frame 2. The resin frame 20 includes a side surface member 21 configuring an upper surface and a part of side surfaces in the left-right direction of the frame 2, and a cover member 22 configuring the front surface of the frame 2. The side surface member 21 is fixed to the die-cast frame 10, and the cover member 22 is fixed to the side surface member 21 via a fitting portion 22a.

The attachment 100 is a member provided for fixing the motor control device 1 to another device or a fixing member such as a wall surface. The attachment 100 is made of, for example, metal. The attachment 100 is fixed to the lower surface (the surface in the lower direction D) of the frame 2. In the example illustrated in FIG. 1, by fixing the attachment 100 to another device, a wall surface, or the like, the motor control device 1 can be fixed to the other device, the wall surface, or the like such that the lower surface of the frame 2 faces the other device, the wall surface, or the like.

The attachment 100 includes a base plate portion 101, attachment plate portions 102, and extension portions 103.

The base plate portion 101 is a plate-shaped portion of the attachment 100 fixed to the frame 2 side. The base plate portion 101 extends substantially parallel to the lower surface of the frame 2. The base plate portion 101 has screw holes through which screws for fixing to the frame 2 is inserted. The base plate portion 101 is fixed to the lower surface of the frame 2 by the screws.

The extension portion 103 is a plate-shaped portion that connects the base plate portion 101 and the attachment plate portion 102. The extension portions 103 extend downward from both ends of the base plate portion 101 in the left-right direction.

The attachment plate portion 102 is a plate-shaped portion of the attachment 100 fixed to another device, a wall surface, or the like. The attachment plate portions 102 are provided at both end portions of the attachment 100 in the left-right direction. The attachment plate portion 102 positioned on a left side of the base plate portion 101 extends from a lower end of the extension portion 103 on a left side in the left direction substantially parallel to the base plate portion 101 and the lower surface of the frame 2. The attachment plate portion 102 positioned on a right side of the base plate portion 101 extends from the lower end of the extension portion 103 on a right side in the right direction substantially parallel to the base plate portion 101 and the lower surface of the frame 2.

The attachment plate portion 102 has attachment holes 110 into which screws for attaching the attachment 100 to the wall surface or the like is inserted. The attachment hole 110 penetrates in the upper-lower direction in FIG. 1. In the present embodiment, the attachment hole 110 opens to one side in the left-right direction. In the attachment 100 having such a configuration, since the frame 2 can be fixed to be separated from another device, a wall surface, or the like as an attachment target by the extension portion 103, it is possible to reduce vibration or heat that the motor control device 1 receives from another device or the like as an attachment target.

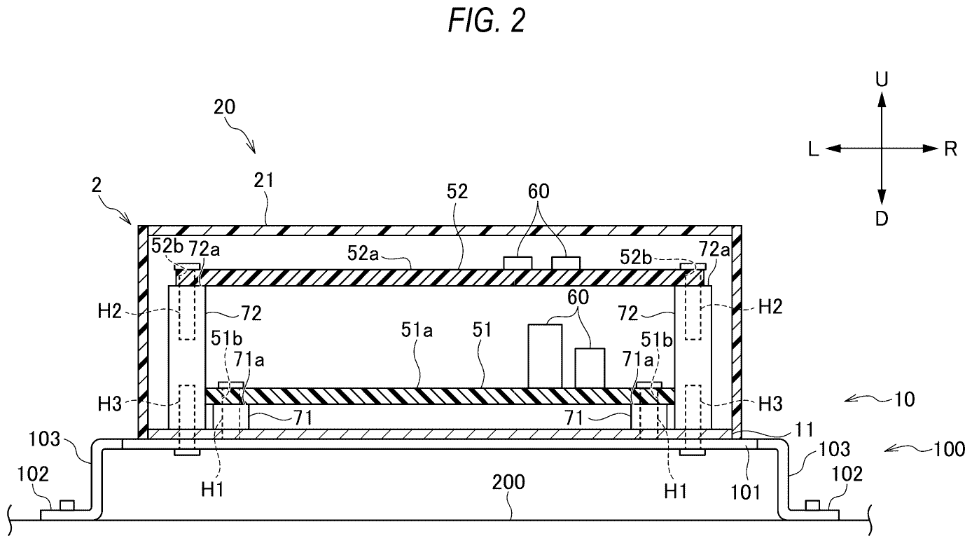

FIG. 2 is a sectional view taken along a line II-II in FIG. 1. As illustrated in FIG. 2, the motor control device 1 further includes a first board 51 and a second board 52, in the accommodation space covered by the frame 2.

The first board 51 and the second board 52 are resin printed boards having wiring patterns formed on surfaces thereof. The first board 51 is provided at a position sandwiched between the die-cast frame 10 and the second board 52.

Electronic components 60 are provided on the first board 51 and the second board 52. The first board 51 has a first mounting surface 51a to which the electronic component 60 is attached and a through hole 51b into which a screw for fixing the first board 51 is inserted. The second board 52 has a second mounting surface 52a to which the electronic component 60 is attached and a through hole 52b into which a screw for fixing the second board 52 is inserted. The second mounting surface 52a of the second board 52 is larger than the first mounting surface 51a of the first board 51, in the front-rear direction and the left-right direction.

In the present embodiment, the electronic component 60 attached to the first board 51 and the second board 52 is, for example, a switching element such as an insulated gate bipolar transistor (IGBT), a capacitor, a transformer, a diode, a resistor, or the like. Note that, in the present embodiment, a separation distance from the first board 51 to the second board 52 is longer than a separation distance from the second board 52 to an upper surface portion of the frame 2. Therefore, the first board 51 is provided with an electronic component 60 having a height dimension larger than those of another electronic components 60, such as a transformer and a capacitor.

Next, a support mode of the first board 51 and the second board 52 using the frame 2 will be described in detail. As illustrated in FIG. 2, the die-cast frame 10 of the frame 2 has a first boss portion 71 and a second boss portion 72 extending upward from the plate-shaped portion 11. The first boss portion 71 is configured to support the first board 51. The second boss portions 72 is configured to support the second board 52.

Each of the first boss portion 71 has a first screw hole H1 for attaching the first board 51. The first screw hole H1 opens at an upper end portion of the first boss portion 71 and penetrates the first boss portion 71 and the plate-shaped portion 11 in the upper-lower direction. The first board 51 is fixed to the first boss portion 71 using the through hole 51b of the first board 51 and a screw inserted into the first screw hole H1.

The second boss portion 72 has a second screw hole H2 for attaching the second board 52. The second screw hole H2 opens at an upper end portion of the second boss portion 72 and extends downward of the second boss portion. The second board 52 is fixed to the second boss portion 72 using the through hole 52b of the second board and a screw inserted into the second screw hole H2.

The second boss portion 72 has a third screw hole H3 into which a screw for fixing the attachment 100 can be inserted. As illustrated in FIG. 2, the second boss portion 72 has the second screw hole H2 at an upper end portion and the third screw hole H3 at a lower end portion. The third screw hole H3 opens in the lower surface of the plate-shaped portion 11 and extends upward from the plate-shaped portion 11 to the second boss portion 72. The base plate portion 101 of the attachment 100 is fixed to the frame 2 using a screw inserted into the third screw hole H3.

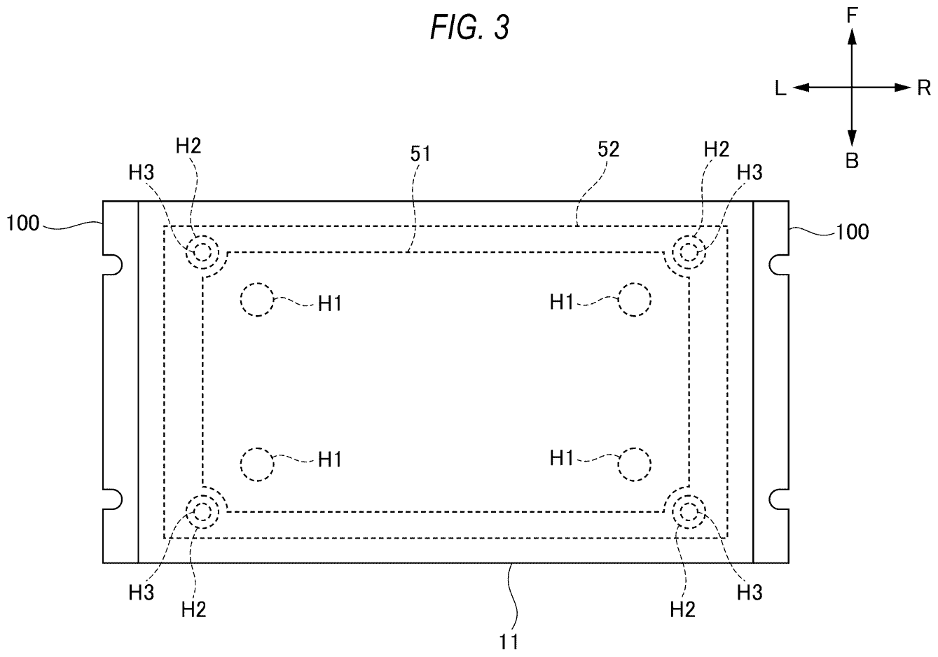

FIG. 3 is a top view illustrating the motor control device 1 according to the present disclosure. As illustrated in FIG. 3, the die-cast frame 10 has four first screw holes H1, four second screw holes H2, and four third screw holes H3.

As illustrated in FIG. 3, the first screw hole H1 is provided at a position where the first screw hole H1 does not overlap the second screw hole H2, when viewed from above. That is, as illustrated in FIG. 3, the first boss portion 71 and the second boss portion 72 are provided at positions where the first boss portion 71 and the second boss portion 72 do not overlap each other, in a top view.

As illustrated in FIG. 3, the third screw hole H3 provided in the second boss portion 72 is provided at a position where the third screw hole H3 overlaps the second screw hole H2 provided in the second boss portion 72, in a top view. Note that, a center of the third screw hole H3 and a center of the second screw hole H2 may not coincide with each other in a top view.

As illustrated in FIG. 2, the first boss portion 71 is shorter than the second boss portion 72, in the upper-lower direction. In other words, a tip end surface 71a of the first boss portion 71 in the upper direction is provided at a position closer to the plate-shaped portion 11 than is a tip end surface 72a of the second boss portion 72. With the above configuration, the first board 51 supported by the first boss portion 71 is supported at a position closer to the plate-shaped portion 11 of the die-cast frame 10 than is the second board 52 supported by the second boss portion 72.

As illustrated in FIG. 3, the first board 51 is provided so as to be covered with the second board 52, in a top view. The first board 51 is cut out at any position so as not to interfere with the second boss portion 72 supporting the second board 52. For example, in the present embodiment, as illustrated in FIG. 3, four corners of the first board 51 are cut out so as not to interfere with the second boss portion 72.

In the related art, there is known a motor control device configured to attach a plurality of boards to a die-cast frame for the purpose of miniaturization. In the motor control device described above, the screw hole for fixing the first board and the screw hole for fixing the second board may be provided at overlapping positions when viewed from a direction orthogonal to an attachment surface of the electronic component. However, in this configuration, since an additional member such as a spacing tube or a spacer is required to attach the board, there is a possibility that assembly workability is reduced.

In the motor control device 1 according to the present disclosure, in a case where the first board 51 and the second board 52 are attached to the die-cast frame 10, first, the first board 51 is screwed to the first screw hole H1 of the first boss portion 71, and then the second board 52 is screwed to the second screw hole H2 of the second boss portion 72. According to the configuration of the present disclosure, the first screw hole H1 for attaching the first board 51 and the second screw hole H2 for attaching the second board 52 are provided at non-overlapping positions, when viewed from a direction orthogonal to the first mounting surface 51a of the first board 51. As a result, the boards are easily screwed to the die-cast frame 10, so that the plurality of boards are easily attached.

In the related art, a mode is known in which a frame of a motor control device is attached to another device, a wall surface, or the like by providing an attachment to the motor control device. In this mode, it is necessary to screw the attachment to one of outer peripheral surfaces of the frame. However, since a plurality of screw holes for attaching the board are provided in a surface of the frame extending parallel to the board, it is difficult to provide the screw holes for attaching the attachment due to a limited space.

Therefore, in the motor control device of the related art, the attachment may be provided on a surface of the outer peripheral surfaces of the frame orthogonal to the direction in which the board extends. However, according to the above configuration, when the motor control device is attached to the wall surface or the like, the motor control device protrudes from the attached wall surface or the like by at least the length of the board since the board is erected perpendicular to the wall surface or the like. As a result, the motor control device may compress a surrounding space.

According to the configuration of the present disclosure, the second screw hole H2 for attaching the second board 52 and the third screw hole H3 for attaching the attachment 100 are provided at overlapping positions, when viewed from the direction orthogonal to the first mounting surface 51a. Accordingly, the attachment 100 can be attached parallel to the board. As a result, a protrusion length when the motor control device 1 is attached to another device, a wall surface, or the like can be reduced, and the surrounding space is not compressed.

In the present embodiment, the second screw hole H2 is provided at a position not overlapping the first board 51, when viewed from the direction orthogonal to the first mounting surface 51a. According to this configuration, in the assembly of the motor control device 1, the second board 52 is easily attached even after the first board 51 is attached to the frame 2. This makes it possible to provide the motor control device 1 that is easy to assemble.

As illustrated in FIG. 2, in the motor control device 1 according to the present disclosure, the attachment 100 may be attached to a movable device 200. In the motor control device 1 according to the present disclosure, the attachment 100 can be attached along a surface parallel to the first board 51 and the second board 52, and the attachment 100 can be attached such that a wall surface or the like is substantially parallel to the first board 51 and the second board 52 of the motor control device 1. As a result, the center of gravity of the motor control device 1 can be brought closer to the attachment target, and thus the attachment of the motor control device 1 is stabilized. The motor control device 1 having the above configuration is particularly effective when attached to a moving device.

Note that, in the embodiment described above, an example in which four first boss portions 71 and four second boss portions 72 are provided has been described, but the number of first boss portions 71 and second boss portions 72 is not limited to the mode described above. The number of the first boss portions 71 may be any number as long as the first board 51 can be supported. Similarly, the number of the second boss portions 72 is not particularly limited as long as the second board 52 can be supported.

In the embodiment described above, an example in which the plate-shaped portion 11 and the back surface portion 12 of the die-cast frame 10 are integrally molded has been described, but the present disclosure is not limited thereto. For example, the plate-shaped portion 11 and the back surface portion 12 may be die-cast and fixed to each other by screwing or fitting.

In the embodiment described above, an example in which the second mounting surface 52a of the second board 52 is larger than the first mounting surface 51a of the first board 51 in the front-rear direction and the left-right direction has been described, but the present disclosure is not limited thereto. For example, the first mounting surface 51a may be larger than the second mounting surface 52a in at least one of the front-rear direction and the left-right direction as long as the first screw hole H1 and the second screw hole H2 do not in a position overlapping each other in a top view. In the configuration described above, the first board 51 may be provided with a notch or a hole through which the second boss portion 72 penetrates at any position so as not to interfere with the second boss portion 72 that supports the second board 52.

Although the embodiment of the present disclosure has been described above, it is needless to say that the technical scope of the present disclosure should not be construed as being limited by the description of the embodiment. It should be understood by those skilled in the art that the present embodiment is merely an example, and various modifications of the embodiment are possible within the scope of the invention described in the claims. The technical scope of the present disclosure should be determined based on the scope of the invention described in what is claimed is and the equivalent scope thereof.

What is claimed is:

1. A motor control device comprising:
a first board including a first mounting surface on which an electronic component is mounted;
a second board extending parallel to the first board and including a second mounting surface larger than the first mounting surface;
a die-cast frame configured to support the first board and the second board; and
an attachment configured to attach the motor control device to a fixing member,
wherein the first board is provided at a position where the first board is sandwiched between the second board and the die-cast frame, in a direction orthogonal to the first mounting surface,
at least a part of the second board is provided so as to cover the first board, when viewed from the direction orthogonal to the first mounting surface,
the die-cast frame has:
a first screw hole for attaching the first board;
a second screw hole for attaching the second board; and
a third screw hole for attaching the attachment, and
when viewed from the direction orthogonal to the first mounting surface:
the first screw hole and the second screw hole are provided at positions where the first screw hole and the second screw hole do not overlap each other; and
the second screw hole and the third screw hole are provided at positions where the second screw hole and the third screw hole overlap each other.

2. The motor control device according to claim 1,
wherein the second screw hole is provided at a position where the second screw hole does not overlap the first board, when viewed from the direction orthogonal to the first mounting surface.

3. The motor control device according to claim 1,
wherein the die-cast frame includes a plate-shaped portion extending parallel to the first board,
the first screw hole is provided on a tip end surface of a first boss portion protruding from the plate-shaped portion toward the first board, and
the second screw hole is provided on a tip end surface of a second boss portion protruding from the plate-shaped portion toward the second board.

4. The motor control device according to claim 3,
wherein the tip end surface of the first boss portion is provided at a position closer to the plate-shaped portion than is the tip end surface of the second boss portion.

5. The motor control device according to claim 1,
wherein the attachment is attached to a movable device.
